(19) United States
(12) Patent Application Publication
(10) Pub. No.: US 2025/0294737 A1
(43) Pub. Date: Sep. 18, 2025

(54) MEMORY CHIP BASED ON TWO-DIMENSIONAL (2D) FLASH MEMORIES WITH COMPLEMENTARY METAL-OXIDE-SEMICONDUCTOR (CMOS) TECHNOLOGY AND ITS FABRICATION METHOD

(71) Applicant: Fudan University, Shanghai (CN)

(72) Inventors: Chunsen LIU, Shanghai (CN); Tanjun WANG, Shanghai (CN); Peng ZHOU, Shanghai (CN)

(21) Appl. No.: 19/224,655

(22) Filed: May 30, 2025

(30) Foreign Application Priority Data
Mar. 11, 2025 (CN) 202510282370.7

(51) Int. Cl. H10B 41/30; H10D 30/01; H10D 30/47

(52) U.S. Cl. CPC H10B 41/30; H10D 30/017; H10D 30/481

(57) ABSTRACT

A memory chip based on two-dimensional (2D) flash memories with complementary metal oxide semiconductor (CMOS) technology, including a substrate structure with a memory peripheral circuit and a 2D material flash memory array. The substrate structure is fabricated using CMOS technology, and the flash memory array is constructed from 2D material-based flash memories. The substrate is prepared by a standard CMOS process and includes different doping types of silicon on the substrate, metal wires for interconnections between devices, and dielectric layers for isolation. The flash memory array has a multi-layer structure.

### CROSS-REFERENCE TO RELATED APPLICATIONS

This application claims the benefit of priority from Chinese Patent Application No. 202510282370.7, filed on Mar. 11, 2025. The content of the aforementioned application, including any intervening amendments made thereto, is incorporated herein by reference in its entirety.

### TECHNICAL FIELD

This application relates to semiconductor memories, and more particularly to a memory chip based on two-dimensional (2D) flash memories with complementary metal-oxide-semiconductor (CMOS) technology, and its fabrication method.

### BACKGROUND

Existing memory technologies are dominated by volatile memories such as dynamic random access memory (DRAM) and static random access memory (SRAM), but these RAMs generally suffer from high power consumption due to the data volatility. Mainstream non-volatile memory is limited by the intrinsic properties of silicon: the typical program speed of the Si-based flash memories (about 100 μs) is much lower than that of volatile memories.

Moore's Law has gradually come to an end in recent years. Various three-dimensional integrated flash memory technologies, including bit-cost scalable (BiCS), pipe-shaped BiCS (PBiCS) and vertical NAND (V-NAND), have been proposed to increase the memory capacity. These architectures can be categorized into channel-stacked and gate-stacked structures. Gate-stacked V-NAND is the first commercialized 3D-NAND architecture, using polycrystalline silicon for the vertical channels and Si₃N₄ as the charge-trap layer. Currently, most leading manufacturers including Samsung, SK Hynix, Micron, and Yangtze Memory have achieved the mass production of devices with more than 200 stacked layers.

Two-dimensional (2D) material-based flash memories, due to their unique properties, demonstrate significant potential for enhancing the storage performance and dimensional scaling of memory chips. However, there are still many challenges in the practical application and development of these memories. Firstly, the current 2D material-based logic devices still need to be improved, making it difficult to implement the peripheral circuitry corresponding to 2D material-based flash memories and fabricate memory chips entirely from 2D materials. Secondly, the 2D material channels are too thin to be compatible with the conventional high-temperature and high-energy semiconductor manufacturing processes, making 3D integration of a single chip and improved memory capacity extremely challenging.

### SUMMARY

The purpose of the present disclosure is to provide a memory chip based on two-dimensional (2D) flash memories with CMOS technology and its fabrication method, which can achieve the improvement of memory density and performance while maintaining the nanosecond programming capability.

A memory chip (with a cross-sectional structure shown in FIG. 1) based on two-dimensional (2D) flash memories with complementary metal-oxide-semiconductor (CMOS) technology is provided herein, which includes a substrate structure and a 2D material flash memory array, as shown in FIG. 2.

The substrate structure is provided with a memory peripheral circuit fabricated using CMOS technology; and the 2D material flash memory array is constructed by a plurality of 2D material-based flash memories.

As shown in the lower right figure of FIG. 2, the substrate structure includes a silicon wafer substrate (1) is provided at a bottom thereof, a N-type silicon active region (2) is provided on the surface of the silicon wafer substrate and is configured as a source and a drain of a N-type metal oxide semiconductor (NMOS) device; a P-type silicon active region (3) is provided on the surface of the silicon wafer substrate and is configured as a source and a drain of a P-type metal-oxide-semiconductor (PMOS) device; metal wires (7) are provided at the N-type silicon active regions and the P-type silicon active regions, and are configured for metal-semiconductor contact between the N-type silicon active region and the P-type silicon active region and for interconnection between the NMOS device and the PMOS device; and an isolation layer is provided between the metal wires, and is made of a low dielectric constant material (4) (relative dielectric constant εᵣ<3.9).

In an embodiment, the materials of the silicon wafer substrate, active region, metal wire, and isolation layer are determined with reference to the materials used in the specific silicon-based process node.

As shown in the upper right figure of FIG. 2, the 2D material flash memory array has a multi-layer structure; each layer of the 2D material flash memory array includes a first metal layer, a first dielectric layer, a second metal layer, a second dielectric layer, a 2D material channel layer and a third dielectric layer. The first metal layer covers the memory peripheral circuit substrate and is configured as a gate electrode (7) of each of the plurality of 2D material-based flash memories; the first dielectric layer covers the first metal layer, and is configured as a blocking layer (5); the second metal layer covers the first dielectric layer, is provided at a middle of the first metal layer, and is configured as a floating gate (7) of each of the plurality of 2D material-based flash memories; the second dielectric layer covers the second metal layer, and is configured as a tunneling layer (5) of each of the plurality of 2D material-based flash memories; the 2D material channel layer (6) covers the tunneling layer and is covered by the third metal layer, the third metal layer is configured as sources and drains of the plurality of 2D material-based flash memories; the third dielectric layer covers the 2D material channel layer, and is provided between the 2D material channel layer and the first metal layer of an adjacent layer in the 2D material flash memory array, and is configured as a buffer layer (4); the third dielectric layer is made of a low dielectric constant material; and adjacent two layers of the 2D material flash memory array are connected through vias.

In an embodiment, the first metal layer is a laminate formed by a first Cr layer with a thickness of 5-10 nm, a first Au layer with a thickness of 80-100 nm and a first Pt layer with a thickness of 5-10 nm

In an embodiment, the second metal layer is made of Pt with a thickness of 1-10 nm.

In an embodiment, the source or the drain (12 or 13) of the plurality of 2D material-based flash memories is made of a Cr—Au laminate with a thickness of 50-100 nm.

In an embodiment, the blocking layer is provided between the floating gate (15) and the gate electrode (14), and is made of HfO₂ with a thickness of 14-20 nm.

In an embodiment, the tunneling layer is provided between the floating gate (15) and the source or the drain (12 or 13) of the plurality of 2D material-based flash memories, and is made of HfO₂ with a thickness of 7-10 nm.

In an embodiment, the third dielectric layer is made of cross-linked polyvinyl alcohol (PVA) with a thickness of 500-700 nm.

In an embodiment, the isolation layer is made of SiO₂ with a thickness of 100-300 nm.

In an embodiment, the 2D material channel layer is made of MoS₂.

In an embodiment, each of the vias is provided with a deposited laminate formed by a second Cr layer with a thickness of 5-10 nm, a second Au layer with a thickness of 80-100 nm and a second Pt layer with a thickness of 5-10 nm.

As shown in FIG. 3, a method for fabricating the memory chip mentioned above include the following steps.

(S1) The substrate structure with the memory peripheral circuit is preparing through CMOS technology.

(S2) The substrate structure is cleaned and wires required by the plurality of 2D material-based flash memories are led out from the substrate structure.

(S3) Dielectric laminate is deposited through patterning exposure, metal deposition and dielectric material deposition.

(S4) A 2D material is transferred from a growth substrate of the 2D material onto the substrate structure using a 2D material transfer technique, followed by the patterning exposure and an etching.

(S5) The source and the drain of each of the plurality of 2D material-based flash memories are formed using the patterning exposure and the metal deposition, followed by deposition of a buffer layer and a material of the isolation layer.

(S3), (S4) and (S5) are repeated to achieve multi-layer stacking, so as to form the multi-layer structure of the 2D material flash memory array.

In an embodiment, the node of the standard CMOS process is the “0.13 μm” technology node.

In an embodiment, the patterning exposure includes electron beam lithography (EBL), ultraviolet lithography (UVL), laser direct writing.

In an embodiment, the process of the metal deposition includes physical vapor deposition (PVD), electron beam evaporation (EBE).

In an embodiment, the process of the dielectric material deposition includes atomic layer deposition (ALD), physical vapor deposition (PVD), chemical vapor deposition (CVD).

In an embodiment, the process of the dielectric material etching includes reactive ion etching (RIE), inductively coupled plasma etching (ICP).

A memory chip based on 2D flash memories with CMOS technology, and its fabrication method provided herein further include the following technical solution.

### Flash Memory Array Stacking Process Design

In the step of stacking the 2D material-based flash memories in the fabrication (see FIG. 4), a non-destructive dielectric layer (10) is transferred onto the surface of the 2D channel material (9) to achieve physical isolation between materials. This isolation layer prevents the more aggressive processing of the low dielectric constant material (11) from damaging the underlying channel material (9), thereby realizing stable, non-destructive interlayer separation.

### Flash Device Structural Design

Each 2D material-based flash memory is shown in FIG. 5 and includes a gate electrode (14), a floating gate (15), and source/drain (12 and 13); a low dielectric constant layer (4) provides inter-device isolation; a high dielectric constant layer (5) serves as both a blocking layer and a tunneling layer; and the 2D material (6) forms the 2D material channel layer. These elements, when interconnected electrically, constitute the basic circuit of the 2D material-based flash memory. By increasing the area of the floating gate (15), coupling efficiency between the gate (14) and the 2D material channel layer is enhanced, improving programming efficiency.

### Flash Memory Array Architecture Design

As shown in FIG. 6, due to the ultrafast performance of the flash devices, the 2D material flash memory array has a parallel arrangement structure; those among the plurality of 2D material-based flash memories in the same row of the 2D material flash memory array share the same word line; those among the plurality of 2D material-based flash memories in the same column of the 2D material flash memory array share the same bit line and the same source line. The 2D material flash memory array is configured to be operated through steps of: 1) applying a positive voltage to a word line corresponding to a selected flash memory, applying a negative voltage to a bit line corresponding to the selected flash memory, and float a source line corresponding to the selected flash memory, so as to implement a program operation of the selected flash memory; 2) applying a negative voltage to a word line corresponding to a selected flash memory, applying a positive voltage to a bit line corresponding to the selected flash memory, and grounding a source line corresponding to the selected flash memory, so as to implement an erase operation of the selected flash memory; 3) applying a positive voltage to a bit line corresponding to a selected flash memory, grounding a source line and a word line corresponding to the selected flash memory, applying a negative charge to other word lines in the 2D material flash memory array, and grounding other bit lines and other source lines in the 2D material flash memory array, so as to implement a read operation of the selected flash memory.

### BRIEF DESCRIPTION OF THE DRAWINGS

FIG. 1 is a sectional view of a flash memory chip according to an embodiment of the present disclosure.

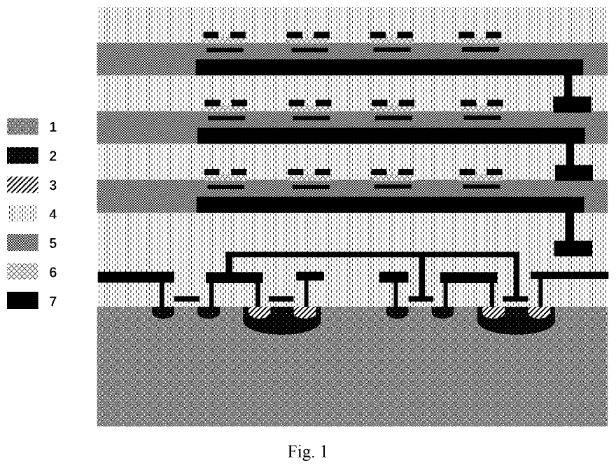

FIG. 2 schematically shows structure of the flash memory chip according to an embodiment of the present disclosure.

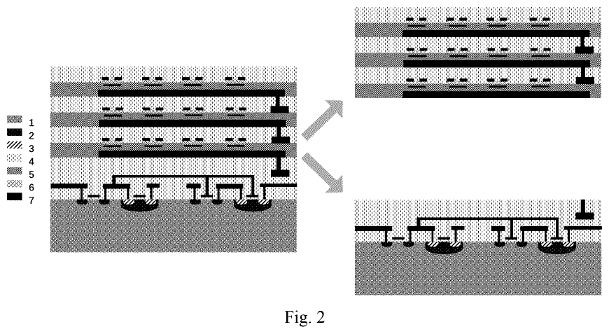

FIG. 3 schematically shows fabrication of the flash memory chip according to an embodiment of the present disclosure.

FIG. 4 schematically illustrates a stacking principle used in the 2D material-based flash memories according to an embodiment of the present disclosure.

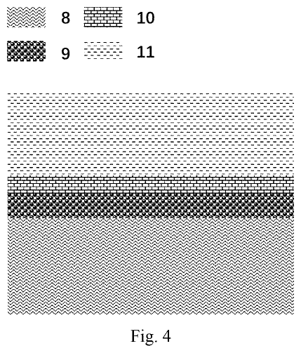

FIG. 5 is a structural diagram of the 2D material-based flash memories according to an embodiment of the present disclosure.

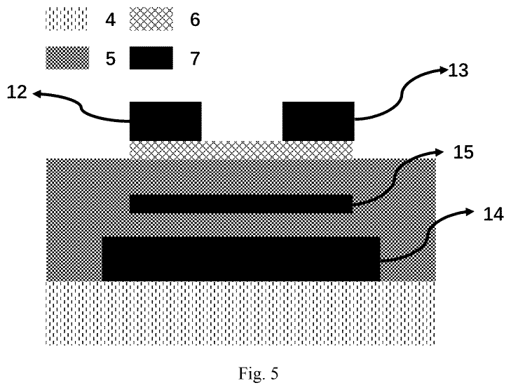

FIG. 6 schematically shows the circuit connection among the 2D material-based flash memories according to an embodiment of the present disclosure.

In the figures, 1—undoped silicon (Si); 2—heavily-doped N-type Si, 3—heavily-doped P-type silicon Si; 4—first low dielectric constant material (e.g. polyvinyl alcohol (PVA), SiO₂); 5—high dielectric constant material (e.g. Al₂O₃, HfO₂); 6—2D material (e.g. MoS₂, WSe₂); 7—various metal materials (e.g. Pt, Au, Cr, Ti, Ni); 8—substrate structure; 9—2D channel material (e.g. MoS₂, WSe₂); 10—buffer layer material (e.g. transferred cross-linked PVA); 11—second low dielectric constant material (e.g. SiO₂); 12—source; 13—drain; 14—gate electrode; 15—floating gate. BL, WL, and SL represent the bit line, word line, and source line of the 2D material flash memory array, respectively.

### DETAILED DESCRIPTION OF EMBODIMENTS

The present disclosure is further illustrated below through embodiments in conjunction with the accompanying drawings.

Many specific details of the present disclosure, such as the structure, materials, dimensions, processing methods and techniques of the devices, are described below to facilitate the understanding of the disclosure. Unless otherwise specified, various parts of the device may be made of materials well known to those skilled in the art.

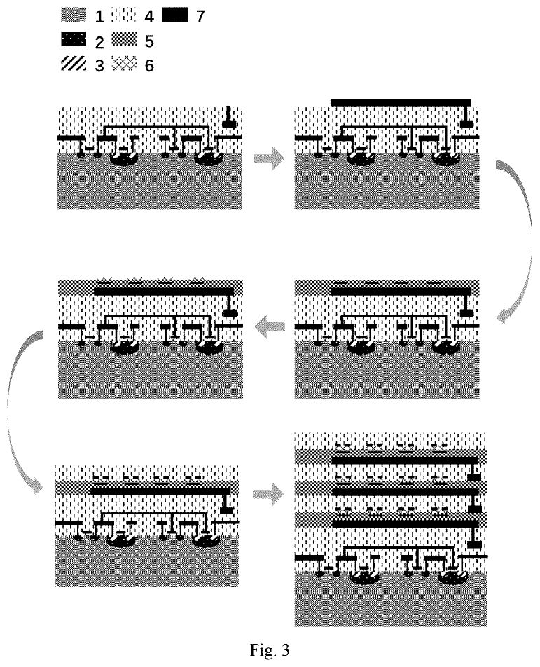

The method provided herein for fabricating the 3D-stacked CMOS flash memories based on 2D material flash memories is shown in FIG. 3. The specific steps are described as follows.

(S1) A substrate structure containing the peripheral memory circuitry is prepared using CMOS processing.

(S2) The substrate structure is cleaned, and then patterning techniques such as laser direct writing, electron beam lithography (EBL), or ultraviolet (UV) lithography in combination with metal deposition methods such as electron beam evaporation or physical vapor deposition (PVD) are used to form the word line (WL) of the first-layer devices and interconnect lines to the underlying circuitry.

(S3) The gate dielectric/metal/dielectric stack is fabricated through dielectric deposition methods such as atomic layer deposition (ALD) in combination with the metal patterning technique described in step (2).

(S4) The 2D material is transferred onto the substrate structure using a 2D material transfer technique.

(S5) The channel pattern is fabricated using patterning methods such as laser direct writing, EBL, or UV lithography, in combination with wet or dry etching.

(S6) The bit line (BL) and source line (SL) of the first-layer devices are fabricated using the patterning and metal deposition methods described in step (S2).

(S7) Interlayer isolation dielectric stacks are fabricated using transfer techniques, atomic layer deposition, and physical vapor deposition in dielectric integration processes Note that a buffer layer material is transferred first, followed by deposition of a low dielectric constant material. Then, using the patterning and etching techniques described in step (S5) to fabricate the vias.

(8) Steps (S2)-(S7) are repeated to achieve 3D-stacked of the 2D material flash memories.

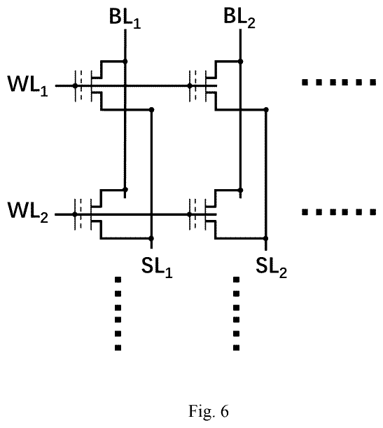

The method for operating the 2D material flash memory array provided by the present disclosure is as follows, as shown in FIG. 6. Taking the operation of the first device in the first row as an example.

Program operation: apply a positive voltage pulse to word line 1, ground all other word lines; apply a negative voltage pulse to bit line 1, ground all other bit lines, and float all source lines.

Erase operation: apply a negative voltage pulse to word line 1, ground all other word lines; apply positive voltage pulses to bit line 1 and source line 1, ground all other source lines.

Read operation: ground word line 1 and bit line 1; apply negative voltages to all other bit lines; ground all other word lines and all source lines.

The above detailed description is intended to enable those skilled in the art to better understand the technical solutions of the disclosure, rather than to limit the disclosure. Various modifications and alterations made without departing from the spirit and scope of the present disclosure are intended to fall within the scope of the disclosure as defined by the appended claims.

What is claimed is:

1. A memory chip based on two-dimensional (2D) flash memories with complementary metal-oxide-semiconductor (CMOS) technology, comprising:
a substrate structure provided with a memory peripheral circuit; and
a 2D material flash memory array;
wherein the substrate structure is fabricated using the CMOS technology; and the 2D material flash memory array is constructed by a plurality of 2D material-based flash memories;
the substrate structure comprises a silicon wafer substrate at a bottom thereof, a N-type silicon active region is provided on a surface of the silicon wafer substrate, and is configured as a source and a drain of a N-type metal oxide semiconductor (NMOS) device; a P-type silicon active region is provided on the surface of the silicon wafer substrate, and is configured as a source and a drain of a P-type metal oxide semiconductor (PMOS) device; metal wires are provided at the N-type silicon active region and the P-type silicon active region, and are configured for metal-semiconductor contact between the N-type silicon active region and the P-type silicon active region and for interconnection between the NMOS device and the PMOS device; and an isolation layer is provided between the metal wires, and is made of a first low dielectric constant material;
the 2D material flash memory array has a multi-layer structure; each layer of the 2D material flash memory array comprises a first metal layer, a first dielectric layer, a second metal layer, a second dielectric layer, a 2D material channel layer, a third metal layer and a third dielectric layer; and
the first metal layer is provided on the substrate structure, and is configured as a gate electrode of each of the plurality of 2D material-based flash memories; the first dielectric layer is configured to cover the first metal layer, and is configured as a blocking layer; the second metal layer is provided at a middle of the first metal layer, and is configured to cover the first dielectric layer, and configured as a floating gate of each of the plurality of 2D material-based flash memories; the second dielectric layer is configured to cover the second metal layer, and is configured as a tunneling layer of each of the plurality of 2D material-based flash memories; the 2D material channel layer is configured to cover the tunneling layer, and is covered by the third metal layer; the third metal layer is configured as sources and drains of the plurality of 2D material-based flash memories; the third dielectric layer is provided between the 2D material channel layer and the first metal layer of an adjacent layer in the 2D material flash memory array, and is configured for buffering and isolation; the third dielectric layer is made of a second low dielectric constant material; and adjacent two layers of the 2D material flash memory array are connected through vias.

2. The memory chip of claim 1, wherein the 2D material flash memory array has a parallel arrangement structure; those among the plurality of 2D material-based flash memories in the same row share the same word line; those among the plurality of 2D material-based flash memories in the same column share the same bit line and the same source line; and
the 2D material flash memory array is configured to be operated through steps of:
applying a positive voltage to a word line corresponding to a selected flash memory, applying a negative voltage to a bit line corresponding to the selected flash memory, and float a source line corresponding to the selected flash memory, so as to implement a program operation of the selected flash memory;
applying a negative voltage to a word line corresponding to a selected flash memory, applying a positive voltage to a bit line corresponding to the selected flash memory, and grounding a source line corresponding to the selected flash memory, so as to implement an erase operation of the selected flash memory; and
applying a positive voltage to a bit line corresponding to a selected flash memory, grounding a source line and a word line corresponding to the selected flash memory, applying a negative charge to other word lines in the 2D material flash memory array, and grounding other bit lines and other source lines in the 2D material flash memory array, so as to implement a read operation of the selected flash memory.

3. The memory chip of claim 1, wherein the first metal layer is a laminate formed by a first Cr layer with a thickness of 5-10 nm, a first Au layer with a thickness of 80-100 nm and a first Pt layer with a thickness of 5-10 nm;
the second metal layer is made of Pt with a thickness of 1-10 nm;
the third metal layer is a Cr—Au laminate with a thickness of 50-100 nm;
the first dielectric layer is provided between the first metal layer and the second metal layer, and is made of HfO₂ with a thickness of 14-20 nm;
the second dielectric layer is provided between the second metal layer and the source or the drain of each of the plurality of 2D material-based flash memories, and is made of HfO₂ with a thickness of 7-10 nm;
the third dielectric layer is made of cross-linked polyvinyl alcohol (PVA) with a thickness of 500-700 nm;
the isolation layer is made of SiO₂ with a thickness of 100-300 nm;
the 2D material channel layer is made of MoS₂; and
each of the vias is provided with a deposited laminate formed by a second Cr layer with a thickness of 5-10 nm, a second Au layer with a thickness of 80-100 nm and a second Pt layer with a thickness of 5-10 nm.

4. A method for fabricating the memory chip of claim 1, comprising:
(S1) preparing the substrate structure with the memory peripheral circuit through CMOS technology;
(S2) cleaning the substrate structure, and leading out wires required by the plurality of 2D material-based flash memories from the substrate structure;
(S3) depositing a dielectric laminate through patterning exposure, metal deposition and dielectric material deposition;
(S4) transferring a 2D material from a growth substrate onto the substrate structure using a 2D material transfer technique, followed by patterning exposure and etching;
(S5) forming the source and the drain of each of the plurality of 2D material-based flash memories via patterning exposure and metal deposition, followed by deposition of a buffer layer and the isolation layer; and
(S6) repeating steps (S3), (S4) and (S5) to achieve multi-layer stacking, so as to form the multi-layer structure of the 2D material flash memory array.
